(19) United States
(12) Patent Application Publication
(10) Pub. No.: US 2026/0172046 A1
(43) Pub. Date: Jun. 18, 2026

(54) LOW POWER FILTERING OF PULSE DENSITY MODULATED DATA USING A DIGITAL FILTER WITH GRAY ENCODING/DECODING

(71) Applicant: STMicroelectronics International N.V., Geneva (CH)

(72) Inventors: Ankur BAL, Greater Noida (IN); Sharad GUPTA, New Delhi (IN)

(73) Assignee: STMicroelectronics International N.V., Geneva (CH)

(21) Appl. No.: 19/386,757

(22) Filed: Nov. 12, 2025

Related U.S. Application Data
(60) Provisional application No. 63/734,819, filed on Dec. 17, 2024.

(51) Int. Cl. H03M 3/00; H03M 7/16

(52) U.S. Cl. CPC H03M 3/462; H03M 7/16

(57) ABSTRACT

A sigma-delta (ΣΔ) analog to digital converter (ADC) circuit receives an analog signal and outputs a pulse density modulated digital signal. A digital filter filters a sequence of data values for the pulse density modulated digital signal. The digital filter includes a multi-stage delay line, an encoder circuit configured to encode data values of the sequence of data values for input to the multi-stage delay line, and decoder circuits configured to decode data values output from corresponding taps of the multi-stage delay line. The encoder may be a Binary to Gray code encoder and the decoder may be a Gray to Binary code decoder.

### CROSS REFERENCE TO RELATED APPLICATIONS

This application claims priority to United States Provisional Application for Patent No. 63/734,819, filed Dec. 17, 2024, the content of which is incorporated by reference.

### TECHNICAL FIELD

The present invention generally relates to a digital signal processing and, more particularly, to the digital filtering of pulse density modulated data.

### BACKGROUND

FIG. 1A shows a block diagram of a sigma-delta (EA) analog to digital converter (ADC) circuit 10. The EA-ADC circuit 10 includes a summing circuit 12 having a first input configured to receive an analog input signal IN 14 and a second input configured to receive an analog feedback signal FB 16. The summing circuit 12 subtracts the feedback signal 16 from the input signal 14 to generate an error signal Er 18. The error signal 18 is filtered by a loop filter 20 to generate a filtered error signal Fer 22. The filtered error signal 22 is quantized by a quantization circuit 24 at a modulation (i.e., sampling rate) frequency determined by a clock signal having a frequency F_{MOD} to generate a pulse density modulated digital signal PDM 26. A digital to analog converter circuit 28 converts the pulse density modulated digital signal 26 to generate the analog feedback signal 16. The pulse density modulated digital signal 26 is further filtered by a digital filter circuit 30 to generate a filtered signal Fpdm 32. The filtered signal 32 is then decimated by a decimation circuit 34 at a decimation rate determined by a clock signal having decimation (i.e., output data rate) frequency F_{ODR} (where F_{MOD}=K×F_{ODR}, and K=the oversampling ratio) to generate a digital output signal Dout 36 which is a digital representation of the analog input signal 14.

The filtering performed by the digital filter circuit 30 is usually a high speed (for example, 1 GHz to 3 GHz) filtering in wideband and radio frequency (RF) ADC circuits. This high speed filtering contributes to a significant power consumption in the ADC circuit. For example, in a wideband, high speed EA-ADC circuit, the high speed digital filtering can contribute between 25-50% of the total digital power consumption. There is a need in the art to reduce the power consumption of the digital filter circuit.

### SUMMARY

In an embodiment, a circuit comprises: a sigma-delta (ΣΔ) analog to digital converter (ADC) circuit having an input configured to receive an analog signal and an output configured to generate a pulse density modulated digital signal including a sequence of data values; and a digital filter configured to receive the sequence of data values for the pulse density modulated digital signal, wherein the digital filter includes a multi-stage delay line, an encoder circuit configured to encode data values of the sequence of data values for input to the multi-stage delay line, and a plurality of decoder circuits configured to decode data values output from corresponding taps of the multi-stage delay line.

In an embodiment, a digital filter circuit comprises: an input configured to receive a filter input signal comprising a sequence of data values; an encoder circuit configured to encode data values of the sequence of data values; a multi-stage delay line having an input configured to receive encoded data values output from the encoder circuit; a plurality of decoder circuits configured to decode data values output from corresponding taps of the multi-stage delay line; and a summation circuit configured to add decoded data values output from the plurality of decoder circuits to generate a filter output signal.

In an embodiment, a digital filter circuit comprises: an input configured to receive a filter input signal comprising a sequence of input data values; an output configured to generate a filter output signal comprising a sequence of output data values; an encoder circuit configured to encode data values of the sequence of output data values; a multi-stage delay line having an input configured to receive encoded data values output from the encoder circuit; a plurality of decoder circuits configured to decode data values output from taps of the multi-stage delay line; and a summation circuit configured to subtract from the filter input signal the decoded data values output from the plurality of decoder circuits to generate the filter output signal.

### BRIEF DESCRIPTION OF THE DRAWINGS

For a better understanding of the embodiments, reference will now be made by way of example only to the accompanying figures in which:

FIG. 1A shows a block diagram of a sigma-delta (ΣΔ) analog to digital converter (ADC) circuit;

FIG. 1B illustrates a representation of a pulse density modulated digital signal;

FIG. 1C is a bar chart illustrating a first difference statistic for the pulse density modulated digital signal of FIG. 1B over a range of frequencies;

FIG. 2A shows a block diagram for a low power digital FIR filtering circuit for filtering a high rate pulse density modulated digital signal;

FIG. 2B shows a block diagram for a low power digital IIR filtering circuit for filtering a high rate pulse density modulated digital signal; and

FIGS. 3A-3B show circuit diagrams for Binary-Gray encoder and decoder circuits.

### DETAILED DESCRIPTION

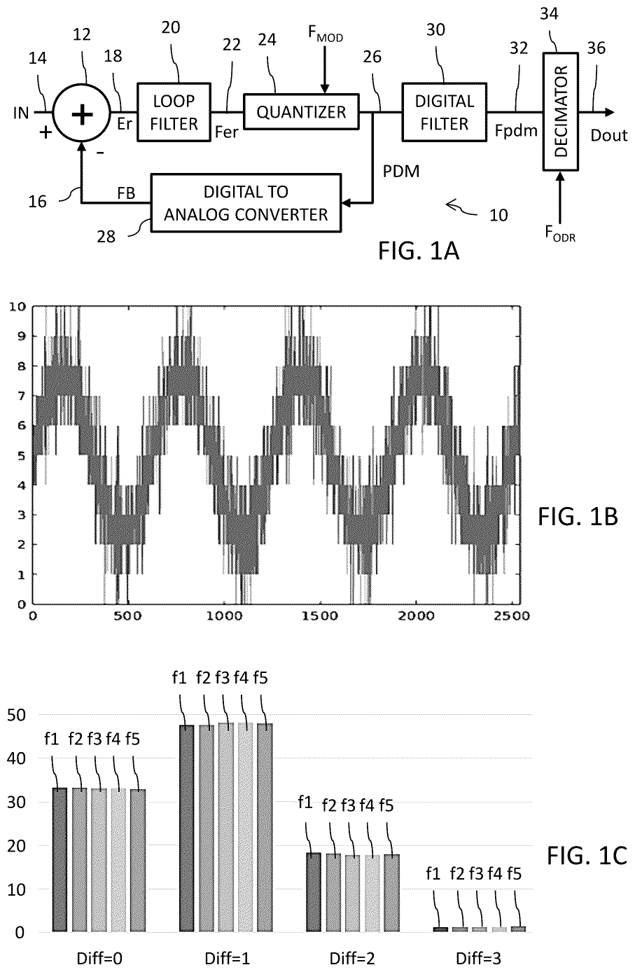

FIG. 1B illustrates a representation of the pulse density modulated digital signal 26 output from the quantization circuit 24 of the modulator. The x-axis shows the digital sample number (range 0 to 2500) and the y-axis shows the decimal value (range 0 to 10) of the signal 26. FIG. 1C shows a bar chart of the first difference statistic for the pulse density modulated digital signal 26, as output from the quantizer circuit 24, at different signal frequencies (for example, f1=2.3 MHz, f2=4.8 MHz, f3=7.5 MHz, f4=10.4 MHz, f5=12.2 MHz). This bar chart illustrates, for each frequency, what percentage of consecutive samples (n, n+1) of the pulse density modulated digital signal 26 have decimal difference (Diff) of 0, 1, 2 or 3, respectively. It will be noted, over the wide range of frequencies from f1 to f5, that close to 50% of the consecutive samples (n, n+1) have a decimal difference of only 1, and the next closest percentage is about 35% for consecutive samples (n, n+1) having a decimal difference of 0. As will be discussed in more detail herein, the implementation of an improved filtering circuit 40 for filtering of the pulse density modulated digital signal 26 takes advantage of this first difference statistic information to provide for a reduced power consumption operation.

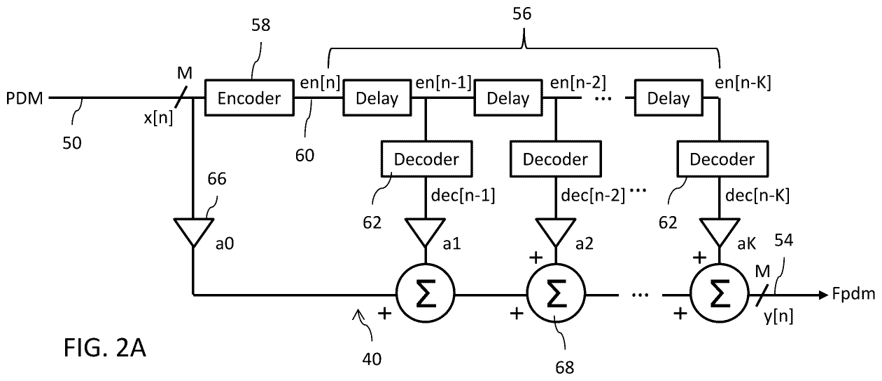

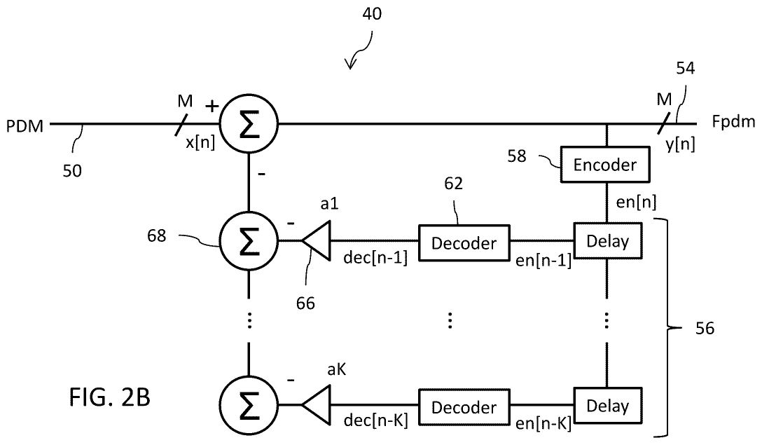

Reference is now made to FIG. 2A which shows a block diagram for a low power digital filtering circuit 40 for filtering a high rate pulse density modulated digital signal. The filtering circuit 40 may be used as the digital filter circuit 30 in the EA-ADC circuit 10 of FIG. 1. The circuit 40 has an input 50 configured to receive data values (or data words) x[n] in a sequence for a pulse density modulated digital signal PDM (for example, signal 26 in FIG. 1) and an output 54 configured to generate data values (or data words) y[n] in a sequence for a filtered signal Fpdm (for example, signal 32 in FIG. 1).

The circuit 40 includes a discrete time digital finite impulse response (FIR)-type filter of order K illustrated in direct form where each sequential value of the filtered signal at the output 54 is a weighted sum of the most recent K+1 values of the input signal received at input 50.

$$y [ n ] = a 0 x [ n ] + a 1 x [ n - 1 ] + … + aK x [ n - K ]$$

$$y [ n ] = {\sum }_{i = 0}^{K} ai x [ n - i ]$$

Where: ai is the applied weight or coefficient of the filter; x is the input signal sequence of M-bit data values; y is the output signal sequence of M-bit data values; and n is the index for the M-bit data values of the input and output sequences of data values.

The filter circuit 40 includes a K-stage delay line 56. Each delay circuit element (Delay) in delay line 56 may comprise, for example, an M-bit data register circuit. Each delay in the delay line 56 is a z⁻¹ operator in Z-transform notation, and thus each delay applies a one unit data value time delay for signal propagation. The output of each delay forms a tap in the K-stage delay line 56. It will be noted, however, that in some filter designs the length of the signal delay provided at each delay in the delay line 56 may differ (for example, there may be provided multiple unit delays for each tap of the delay line).

Before being applied to an input of the K-stage delay line 56, each M-bit data value in the sequence of data values for the input signal received at input 50 (for example, comprising the pulse density modulated digital signal 26 of FIG. 1) is encoded by an encoder circuit 58 to generate an encoded M-bit data value en[n]60. In a preferred embodiment, the encoder circuit 58 is an M-bit Binary to Gray encoder that functions to convert the data value z[n] from a Binary code value to a Gray code value.

The delayed encoded M-bit data value en[n-1], en[n-2, . . . , en[n-K]output from the corresponding taps of the K-stage delay line 56 is processed by a decoder circuit 62 to generate a corresponding delayed decoded M-bit data value dec[n-1], dec[n-2, . . . , dec[n-K]. In a preferred embodiment, the decoder circuit 62 is an M-bit Gray to Binary decoder that functions to convert the received data value from a Gray code value to a Binary code value.

The M-bit input signal data value x[n] and the delayed decoded M-bit data values dec[n-1], dec[n-2], . . . , dec[n-K] are then scaled by multiplication circuits 66 which apply the filter weight or coefficient values a0, a1, a2, . . . , aK, respectively.

The scaled input signal data value x[n] and the scaled delayed decoded data values dec[ ] output from the multiplication circuits 66 are then added by summation circuits 68 to generate M-bit data values of the sequence of data values for the filtered signal at output 54.

The use of the Binary to Gray encoding and Gray to Binary decoding is applicable to any discrete time filter which utilizes a K-stage delay line. Consider, for example, FIG. 2B which shows a filter circuit 40 comprising a discrete time digital infinite impulse response (IIR)-type filter of order K illustrated in direct form. Each sequential value of the filtered signal at the output 54 is a weighted difference of the current value of the input signal received at input 50 and the most recent output values from output 54:

$$y [ n ] = x [ n ] - a 1 y [ n - 1 ] - … - aK y [ n - K ]$$

Before being applied to an input of the K-stage delay line 56, each M-bit data value in the sequence of data values for the output signal at output 54 is encoded by an encoder circuit 58 to generate an encoded M-bit data value en[n]. In a preferred embodiment, the encoder circuit 58 is an M-bit Binary to Gray encoder that functions to convert the received data value from a Binary code value to a Gray code value.

The delayed encoded M-bit data value en[n-1], . . . , en[n-K]output from the corresponding taps of the K-stage delay line 56 is processed by a decoder circuit 62 to generate a corresponding delayed decoded M-bit data value dec[n-1], . . . , dec[n-K]. In a preferred embodiment, the decoder circuit 62 is an M-bit Gray to Binary decoder that functions to convert the data value from a Gray code value to a Binary code value.

The delayed decoded M-bit data values dec[n-1], . . . , dec[n-K] are then scaled by multiplication circuits 66 which apply the filter weight or coefficient values a1, . . . , aK, respectively.

The scaled delayed decoded data values dec[ ] output from the multiplication circuits 66 are then subtracted by summation circuits 68 from the input data value x[n] to generate M-bit data values of the sequence of data values for the filtered signal at output 54.

The conversion between Binary and Gray implemented by the encoder circuit 58 and the decoder circuits 62 is provided by the following table for M=4:

| BINARY CODE | | | | DECIMAL | GRAY CODE | | | |
|---|---|---|---|---|---|---|---|---|
| 0 | 0 | 0 | 0 | 0 | 0 | 0 | 0 | 0 |
| 0 | 0 | 0 | 1 | 1 | 0 | 0 | 0 | 1 |
| 0 | 0 | 1 | 0 | 2 | 0 | 0 | 1 | 1 |
| 0 | 0 | 1 | 1 | 3 | 0 | 0 | 1 | 0 |
| 0 | 1 | 0 | 0 | 4 | 0 | 1 | 1 | 0 |
| 0 | 1 | 0 | 1 | 5 | 0 | 1 | 1 | 1 |
| 0 | 1 | 1 | 0 | 6 | 0 | 1 | 0 | 1 |
| 0 | 1 | 1 | 1 | 7 | 0 | 1 | 0 | 0 |
| 1 | 0 | 0 | 0 | 8 | 1 | 1 | 0 | 0 |
| 1 | 0 | 0 | 1 | 9 | 1 | 1 | 0 | 1 |
| 1 | 0 | 1 | 0 | 10 | 1 | 1 | 1 | 1 |
| 1 | 0 | 1 | 1 | 11 | 1 | 1 | 1 | 0 |
| 1 | 1 | 0 | 0 | 12 | 1 | 0 | 1 | 0 |
| 1 | 1 | 0 | 1 | 13 | 1 | 0 | 1 | 1 |
| 1 | 1 | 1 | 0 | 14 | 1 | 0 | 0 | 1 |
| 1 | 1 | 1 | 1 | 15 | 1 | 0 | 0 | 0 |

The advantage of using the Gray code data values over the Binary code data values is that in Gray code the codes which assign to each value of a contiguous set of integers provide that no two code words are the same and that each two adjacent code words differ by only a single bit change. With reference once again to FIG. 1C, it is recognized for the pulse density modulated digital signal 26 received at input 50 that close to 50% of the consecutive samples (n, n+1) have a decimal difference of 1, and for those samples each latching of a data value in a delay circuit of the K-stage delay line 56 as the encoded data values en[ ] shifting through the K-stage delay line 56 will implicate the toggling of only a single data bit. As a result, there is a significant power savings in the digital filter chain for filter circuit 40 as compared to an FIR of same architecture which does not implement the encoding/decoding operations and where there is a greater percentage of consecutive samples (n, n+1) having a decimal difference which implicates the toggling of two or more data bits in the shift registers of the delay line.

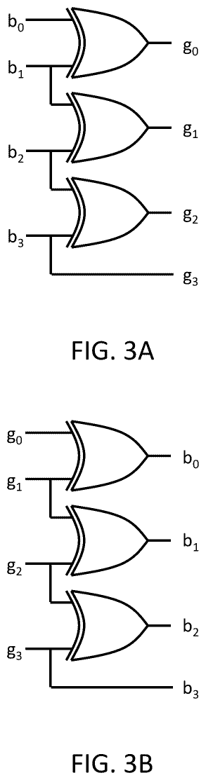

FIG. 3A provides a logic circuit 80 which functions to convert from Binary code to Gray code. The circuit receives an M-bit binary coded input value (b₀, b₁, b₂, . . . , b_{M-1}) and generates an M bit Gray coded output value (g₀, g₁, g₂, . . . , g_{M-1}). In the illustrated example, M=4, corresponding to the foregoing table.

FIG. 3B provides a logic circuit 82 which functions to convert from Gray code to Binary code. The circuit receives an M-bit Gray coded input value (g₀, g₁, g₂, . . . , g_{M-1}) land generates an M bit binary coded output value (b₀, b₁, b₂, . . . , b_{M-1}). In the illustrated example, M=4, corresponding to the foregoing table.

The circuits 80 and 82 are identical to each other and are implemented using only exclusive-OR (XOR) logic gates for fast and low power operation. In this implementation, bits 0 and 1 of the input data value are logically exclusive-OR'ed to generate bit 0 of the output data value, bits 1 and 2 of the input data value are logically exclusive-OR'ed to generate bit 1 of the output data value; bits 2 and 3 of the input data value are logically exclusive-OR'ed to generate bit 2 of the output data value, and bit 3 of the input data value is output as bit 3 of the output data value.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A circuit, comprising:
a sigma-delta (ΣΔ) analog to digital converter (ADC) circuit having an input configured to receive an analog signal and an output configured to generate a pulse density modulated digital signal including a sequence of data values; and
a digital filter configured to receive the sequence of data values for the pulse density modulated digital signal, wherein the digital filter includes a multi-stage delay line, an encoder circuit configured to encode data values of the sequence of data values for input to the multi-stage delay line, and a plurality of decoder circuits configured to decode data values output from corresponding taps of the multi-stage delay line.

2. The circuit of claim 1:
wherein the encoder circuit is a Binary code to Gray code encoder; and
wherein each decoder circuit is a Gray code to Binary code decoder.

3. The circuit of claim 2, wherein the digital filter includes a summation circuit configured to sum decoded data values output from the plurality of decoder circuits to generate a filter output signal.

4. The circuit of claim 3, wherein the digital filter includes a plurality of scaling circuits configured to scale the decoded data values output from the plurality of decoder circuits by filter coefficients prior to being summed to generate the filter output signal.

5. The circuit of claim 1, further including a decimation circuit configured to decimate a sequence of data values output from the digital filter.

6. The circuit of claim 1, wherein the digital filter comprises a finite impulse response filter.

7. The circuit of claim 1, wherein the digital filter comprises an infinite impulse response filter.

8. The circuit of claim 1, wherein the digital filter circuit comprises:
an input configured to receive a filter input signal comprising a sequence of data values;
a Binary code to Gray code encoder circuit configured to encode data values of the sequence of data values;
a multi-stage delay line having an input configured to receive encoded data values output from the encoder circuit;
a plurality of Gray code to Binary code decoder circuits configured to decode data values output from corresponding taps of the multi-stage delay line; and
a summation circuit configured to add decoded data values output from the plurality of decoder circuits to generate a filter output signal

9. The circuit of claim 8, further including a plurality of multiplication circuits configured to scale the decoded data values output from the plurality of decoder circuits before being added by the summation circuit.

10. The circuit of claim 1, wherein the digital filter circuit, comprising:
an input configured to receive a filter input signal comprising a sequence of input data values;
an output configured to generate a filter output signal comprising a sequence of output data values;
a Binary code to Gray code encoder circuit configured to encode data values of the sequence of output data values;
a multi-stage delay line having an input configured to receive encoded data values output from the encoder circuit;
a plurality of Gray code to Binary code decoder circuits configured to decode data values output from corresponding taps of the multi-stage delay line; and
a summation circuit configured to subtract from the filter input signal the decoded data values output from the plurality of decoder circuits to generate the filter output signal

11. The circuit of claim 10, further including a plurality of multiplication circuits configured to scale the decoded data values output from the plurality of decoder circuits before being subtracted by the summation circuit.

12. A digital filter circuit, comprising:
an input configured to receive a filter input signal comprising a sequence of data values;
an encoder circuit configured to encode data values of the sequence of data values;
a multi-stage delay line having an input configured to receive encoded data values output from the encoder circuit;
a plurality of decoder circuits configured to decode data values output from corresponding taps of the multi-stage delay line; and
a summation circuit configured to add decoded data values output from the plurality of decoder circuits to generate a filter output signal.

13. The digital filter circuit of claim 12, further including a plurality of multiplication circuits configured to scale the decoded data values output from the plurality of decoder circuits before being added by the summation circuit.

14. The digital filter circuit of claim 12, wherein the sequence of data values is a pulse density modulated digital signal.

15. The digital filter circuit of claim 12:
wherein the encoder circuit is a Binary code to Gray code encoder; and
wherein each decoder circuit is a Gray code to Binary code decoder.

16. The digital filter circuit of claim 12, further including a decimation circuit configured to decimate a sequence of data values for the filter output signal.

17. A digital filter circuit, comprising:
an input configured to receive a filter input signal comprising a sequence of input data values;
an output configured to generate a filter output signal comprising a sequence of output data values;
an encoder circuit configured to encode data values of the sequence of output data values;
a multi-stage delay line having an input configured to receive encoded data values output from the encoder circuit;
a plurality of decoder circuits configured to decode data values output from corresponding taps of the multi-stage delay line; and
a summation circuit configured to subtract from the filter input signal the decoded data values output from the plurality of decoder circuits to generate the filter output signal.

18. The digital filter circuit of claim 17, further including a plurality of multiplication circuits configured to scale the decoded data values output from the plurality of decoder circuits before being subtracted by the summation circuit.

19. The digital filter circuit of claim 17, wherein the sequence of input data values is a pulse density modulated digital signal.

20. The digital filter circuit of claim 17:
wherein the encoder circuit is a Binary code to Gray code encoder; and
wherein each decoder circuit is a Gray code to Binary code decoder.

21. The digital filter circuit of claim 17, further including a decimation circuit configured to decimate a sequence of output data values.
